(19) United States
(12) Patent Application Publication
(10) Pub. No.: US 2011/0309306 A1
(43) Pub. Date: Dec. 22, 2011

(54) Fabrication of Silicon Nanowires

(75) Inventors: Chongwu Zhou, Arcadia, CA (US); Po-Chiang Chen, Hillsboro, OR (US); Haitian Chen, Los Angeles, CA (US); Jing Xu, Los Angeles, CA (US)

(73) Assignee: UNIVERSITY OF SOUTHERN CALIFORNIA, Los Angeles, CA (US)

(21) Appl. No.: 13/099,199

(22) Filed: May 2, 2011

Related U.S. Application Data
(60) Provisional application No. 61/329,993, filed on Apr. 30, 2010.

(51) Int. Cl. H01B 1/06; C30B 25/00; H01M 4/02; B22F 9/16; C01B 33/02; H01L 21/20; H01M 4/04; B82Y 40/00; B82Y 99/00

(52) U.S. Cl. 252/500; 438/478; 117/88; 75/370; 423/348; 257/E21.09; 257/E29.168; 977/762

(57) ABSTRACT

Nanowires are formed in a process including fluidized bed catalytic vapor deposition. The process may include contacting a gas-phase precursor including a metal or a semiconductor with a catalyst in a reaction chamber under conditions suitable for growth of nanowires including the metal or the semiconductor. The reaction chamber includes a support. The support can be, for example, a particulate support or a product vessel in the fluidized bed reactor. Nanowires are formed on the support in response to interaction between the gas-phase precursor and the catalyst. The nanowire-laden support is removed from the reaction chamber, and the nanowires are separated from the support. An anode or a lithium-ion battery may include nanowires formed in a fluidized bed reactor.

### CROSS-REFERENCE TO RELATED APPLICATIONS

This application claims priority to U.S. Application Ser. No. 61/329,993, filed on Apr. 30, 2010, which is incorporated herein by reference.

### FEDERALLY SPONSORED RESEARCH OR DEVELOPMENT

The invention was made with government support under Computing and Communication Foundations Grant Nos. CCF 0726815 and CCF 0702204 awarded by the National Science Foundation. The government has certain rights in the invention.

### TECHNICAL FIELD

This invention relates to fabrication of silicon nanowires based on fluidized bed catalytic chemical vapor deposition, silicon nanowires formed thereby, and devices including silicon nanowires formed thereby.

### BACKGROUND

Silicon (Si) nanowires, with unique physico-chemical properties, have brought significant breakthroughs in fields such as electronic devices, biochemical sensors, thermoelectronic devices, solar cells, and electrochemical energy conversion and storage devices. In some cases, single crystalline silicon nanowires are preferred over polycrystalline (poly-Si) and amorphous silicon (a-Si) nanowires for use in the applications of electronic devices, biochemical sensors and thermoelectronic devices, because they may have fewer defects and can be stronger and more conductive than polycrystalline and amorphous silicon nanowires of similar diameter.

For use in lithium ion batteries, both single crystalline silicon nanowires and a-silicon nanowires can provide higher specific capacity than graphite and other carbonaceous materials, due to the short electron diffusion length, large interfacial area with electrolyte, and room for volume expansion.

### SUMMARY

In one aspect, nanowires are formed by contacting a gas-phase precursor including a metal or a semiconductor with a catalyst in a reaction chamber under conditions suitable for growth of nanowires including the metal or the semiconductor. The reaction chamber includes a support. Nanowires are grown on the support to yield a nanowire-laden support in response to interaction between the gas-phase precursor and the catalyst. The nanowire-laden support is removed from the reaction chamber, and the nanowires are separated from the support.

In another aspect according to the first aspect, the gas-phase precursor and the catalyst are contacted in a fluidized bed reactor.

In another aspect according to the first aspect, the precursor includes silicon, germanium, zinc, indium, tin, or a combination thereof.

In another aspect according to the first aspect, the catalyst is a gas-phase catalyst.

In another aspect according to the first aspect, the catalyst includes an organometallic compound or a metal. In an example, the catalyst includes gold.

In another aspect according to the first aspect, the nanowires are single crystalline nanowires, polycrystalline nanowires, amorphous nanowires, core/shell nanowires, or a combination thereof. When the nanowires include core/shell nanowires including a core and a shell, the core and the shell are independently single crystalline, polycrystalline, or amorphous.

In another aspect according to the first aspect, the catalyst is disposed on the support, and contacting the gas-phase precursor with the catalyst includes causing the gas-phase precursor to flow over the support.

In another aspect according to the first aspect, the support is a particulate support. The support may be spherical in shape. In some cases, the support includes Al₂O₃. In certain cases, the support is Al₂O₃. The support may be substantially free of the metal or the semiconductor of the precursor.

In another aspect according to the first aspect, the reaction chamber is configured such that the gas-phase precursor flows upwardly through the reaction chamber from an inlet to an exhaust outlet.

In another aspect according to the first aspect, an interior of the reaction chamber is substantially isolated from an environment surrounding the reaction chamber.

In another aspect according to the first aspect, additional amounts of the gas-phase precursor and the catalyst are provided to the reaction chamber while an interior of the reaction chamber is substantially isolated from an environment surrounding the reaction chamber.

In another aspect according to the first aspect, an interior of the reaction chamber is heated to a temperature between 350° C. and 700° C.

Another aspect includes nanowires produced according to the first aspect.

Another aspect includes an anode for a lithium ion half-cell including nanowires produced according to the first aspect.

Another aspect includes a battery including nanowires produced according to the first aspect.

These general and specific aspects may be implemented using a device, system or method, or any combination of devices, systems, or methods. The details of one or more embodiments are set forth in the accompanying drawings and the description below. Other features, objects, and advantages will be apparent from the description and drawings, and from the claims.

### BRIEF DESCRIPTION OF THE DRAWINGS

FIG. 1 depicts a reaction apparatus for horizontal fluidized bed catalytic chemical vapor deposition.

FIG. 2A depicts a spherical support. FIG. 2B depicts a spherical support with catalyst particles on the support. FIG. 2C depicts nanowires synthesized on a spherical support.

FIG. 3 depicts a reaction apparatus for horizontal fluidized bed catalytic chemical vapor deposition.

FIG. 4 depicts a reaction apparatus for horizontal fluidized bed catalytic chemical vapor deposition.

FIG. 5 depicts a reaction apparatus for vertical fluidized bed catalytic chemical vapor deposition.

FIG. 6 depicts a reaction apparatus for continuous fluidized bed catalytic chemical vapor deposition.

FIGS. 7A-7B show high resolution transmission electron microscope (HR-TEM) images of silicon nanowires (scale 100 nm and 10 nm, respectively).

FIG. 8A is a photographic image of Al₂O₃ spheres (scale 4 mm). FIG. 8B is a photographic image of Al₂O₃ spheres on which silicon nanowires have been synthesized. FIG. 8C is a field emission scanning electron microscope (FESEM) image of an Al₂O₃ sphere with silicon nanowires grown on its surface (scale 300 μm).

FIG. 9 is a photographic image of 80 mg of free-standing silicon nanowires in a vial, with a penny shown for reference.

FIG. 10A is a photographic image of silicon nanowires synthesized on Al₂O₃ spheres in a vertical chamber. FIG. 10B is a photographic image of Al₂O₃ spheres stacked in a vertical quartz reaction chamber. FIG. 10C is a scanning electron microscope (SEM) image of a Al₂O₃ sphere with silicon nanowires synthesized on its surface in a vertical chamber reaction apparatus (scale 400 μm).

FIG. 11A is a FESEM image of crystalline-amorphous core/shell silicon nanowires (scale 30 μm). FIG. 11B is a SEM image of a c-a core/shell silicon nanowire with gold at its tip (scale 100 nm). FIG. 11C is a high resolution transmission electron microscope (HR-TEM) image of a c-a core/shell silicon nanowire (scale 250 nm). FIG. 11D is a HR-TEM image of a crystalline-amorphous core/shell interface of a silicon nanowire (scale 10 nm).

FIG. 12 shows a diameter distribution of c-a core/shell silicon nanowires shown in FIGS. 11A-11D.

FIG. 13A is a FESEM image of single crystalline silicon nanowires. FIG. 13B is an image of a crystalline silicon nanowire with a gold particle at its tip. FIG. 13C is a HR-TEM image of a single crystalline silicon nanowire having the growth axis in the <111> direction. FIG. 13D is a HR-TEM image showing the lattice fringes of the nanowire. FIG. 13E is an electron diffraction pattern from a silicon nanowire.

FIG. 14 shows the diameter distribution of the single crystalline nanowires shown in FIGS. 13A-13E.

FIG. 15 shows a cyclic voltammogram from 0.01 V to 3.0 V for silicon nanowires.

FIG. 16 shows a voltage profile for first 40 cycles of a silicon nanowire electrode (C/30 rate).

FIG. 17 shows a plot of capacity versus cycle number for a silicon nanowire electrode (C/30 rate and C/15 rate).

FIG. 18 shows a plot of Coulombic efficiency versus cycle number for a silicon nanowire electrode (C/30 rate and C/15 rate).

### DETAILED DESCRIPTION

Bulk quantities of nanowires are produced by vapor-liquid-solid (VLS) growth mechanisms using catalytic chemical vapor deposition (C-CVD) in fluidized bed reactors. Nanowires produced by these scalable methods include single crystalline nanowires, polycrystalline nanowires, amorphous nanowires, and core/shell nanowires of semi-conductors, metals, alloys, and metal oxides. Examples include single crystal silicon nanowires, polycrystalline silicon nanowires, amorphous silicon nanowires, germanium nanowires, silicon/germanium alloy nanowires, core/shell nanowires with core and shell being any combination of single crystalline, polycrystalline, or amorphous silicon, germanium, or silicon/germanium alloy, and metal oxide nanowires such as zinc oxide nanowires, indium oxide nanowires, and tin oxide nanowires. In some cases, the nanowires have a diameter between about 3 nm and about 300 nm and a length between about 1 μm and about 50 μm.

Silicon nanowires produced as described herein can be used to form the active material in an anode of a lithium ion battery half-cell. Lithium ion batteries are understood to include an anode, a cathode, an electrical pathway therebetween, and an electrolyte between the anode and the cathode. In one example, a traditional slurry method is used to form the anode. In a traditional slurry electrode fabrication process, a current collector is coated with a layer of slurry of amalgamation including active material, conductive composite, and binder. Tens of milligrams of the active material are required in the processing of traditional slurry electrodes. Synthesis of silicon nanowire in bulk quantity can facilitate the use of silicon nanowires in a commercially compatible slurry electrode fabrication process.

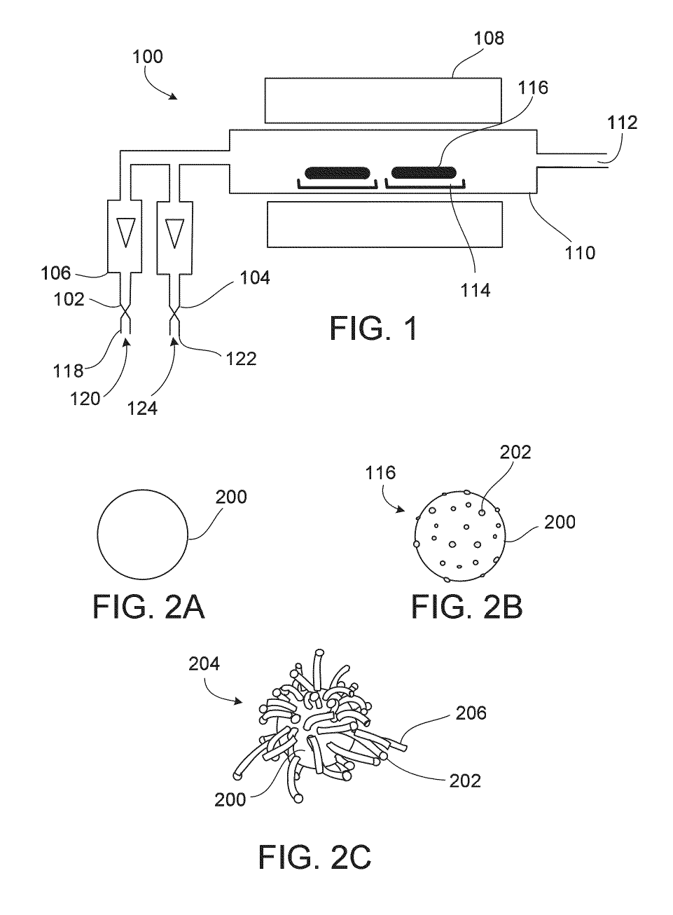

Referring to FIG. 1, reaction apparatus 100 for horizontal fluidized bed C-CVD includes inlets 102 and 104, mass flow controllers 106, furnace 108, reaction chamber 110, and exhaust outlet 112. Reaction chamber 110 may be, for example a quartz chamber. One or more product vessels 114 may be positioned in reaction chamber 110. Supported catalyst 116, including a catalyst disposed on a support, is positioned in product vessels 114. Carrier gas source 118, including carrier gas 120, and precursor gas source 122, including precursor 124, can be coupled to inlets 102 and 104, respectively.

The catalyst support can be a solid of any regular or irregular shape. The solid may be an inorganic solid. The solid may be a particulate solid. The support may include, for example, carbon nanotubes, alumina, silica (SiO₂), alumina-silica, magnesia (Mg(OH)₂), magnesium oxide (MgO), or any combination thereof. The support may be in a flowable form, such as a powder or a multiplicity of spheres, rods, wires, etc. A dimension of the support can be, for example, in a range of about 10 nm to about 100 nm. FIG. 2A depicts spherical support 200.

The catalyst may include an organometallic compound, a metal, or any combination thereof. Examples of catalysts include gold (Au), iron (Fe), aluminum (Al), titanium (Ti), platinum (Pt), silver (Ag), copper (Cu), gallium (Ga), cobalt (Co), nickel (Ni), tungsten (W), molybdenum (Mo), ferrocene (Fe(C₅H₅)₂), iron pentacarbonyl (Fe(CO)₅), and the like, or any combination thereof. Supported catalyst 116 can be prepared by contacting support 200 with a catalyst in methods including sol-gel, impregnation, co-precipitation, annealing, and chemical vapor deposition (CVD) methods. Supported catalyst 116 may include nanoparticles or nanoparticle clusters of catalyst on the surface of support 200. FIG. 2B depicts catalyst 202 disposed (or “decorated”) on spherical support 200 to form supported catalyst 116. Catalyst 202 is in the form of nanoparticle clusters.

During operation, carrier gas 120 from carrier gas source 118 and precursor 124 from precursor gas source 122 flow independently through mass flow controllers 106, and over supported catalyst 116 in reaction chamber 110. Carrier gas 120 and precursor 124 can be provided to reaction chamber 110 with a precursor/carrier volume ratio in a range from about 0.1 to 5. The reaction chamber may be at a temperature between about 350° C. and about 700° C. or the eutectic temperature between the catalyst and the precursor. Examples of precursors 124 include silane compounds, such as silanes, disilanes, trisilanes, chlorosilanes, and silane derivatives. Examples include monosilane, disilane, chlorosilane, dichlorosilane, trichlorosilane, hexachlorosilane, and silicon tetrachloride. Examples of carrier gases 120 include hydrogen (H₂), helium (He), argon (Ar), and nitrogen (N₂). Catalyst 202 serves as a catalytic site for nucleation of precursor 124, promoting growth of nanowires on support 200. FIG. 2C depicts nanowire-laden support 204, with nanowires 206 formed in three dimensions on support 200. Catalyst 202 is seen adhered to ends of nanowires 206. As used herein, a “nanowire-laden” support refers to a support from which a multiplicity of nanowires extend. In some cases, the support may be particulate. In other cases, the support may be, for example, a product vessel. After nanowire-laden support 204 exits reaction chamber 110, the nanowires may be removed from support 200 by agitation in a solvent. Suitable solvents include, for example, isopropyl alcohol, dimethylformamide, n-butanol, n-propanol, ethanol, and methanol. Suitable methods of agitation include mechanical agitation, sonication, etc.

In some cases, gas-phase dopants, such as phosphine (PH₄) and diborane (B₂H₆) can be provided to reaction chamber 110 during nanowire growth, for example, to alter electronic properties of the nanowires. The dopant gas may be combined with the precursor gas in a selected ratio or provided through a separate inlet. In some cases, concentration of a dopant gas is selected by adjusting the ratio of carrier gas and dopant gas.

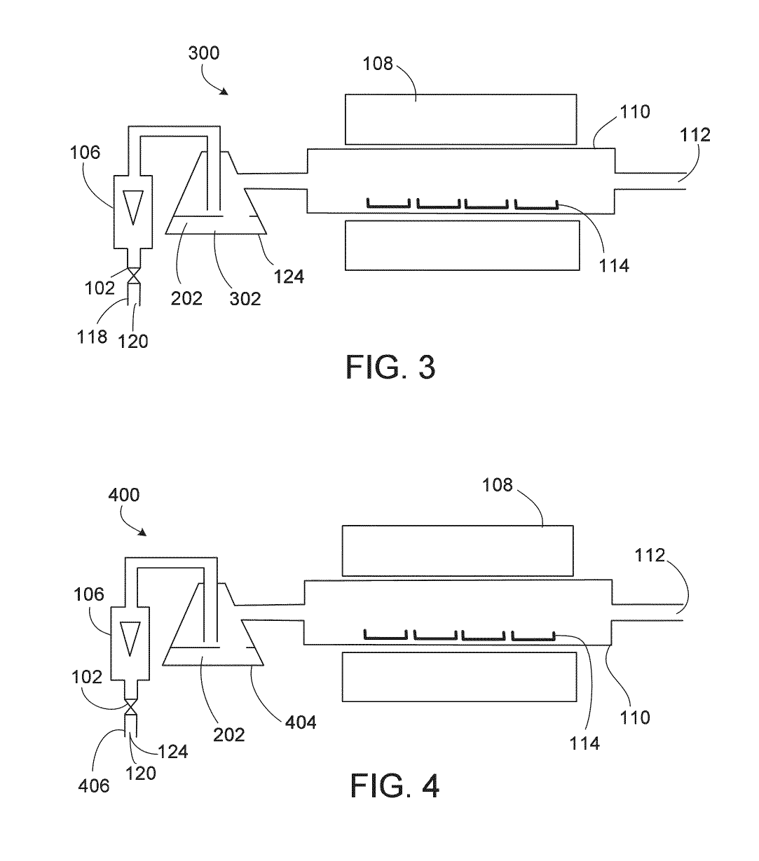

Referring to FIG. 3, reaction apparatus 300 for horizontal fluidized bed C-CVD includes inlet 102, mass flow controller 106, precursor vessel 302, furnace 108, reaction chamber 110, and exhaust outlet 112. One or more product vessels 114 may be positioned in reaction chamber 110. Precursor vessel 302 may include catalyst 202 mixed with or dissolved in precursor 124. The catalyst may be, for example, chloroauric acid. Precursor 124 may be volatile. For example, precursor 124 may be a volatile silicon source such as silicon tetrachloride or trichlorosilane or a volatile germanium source such as germanium tetrachloride. Carrier gas source 118 can be coupled to inlet 102. Other details may be similar to those described with respect to FIG. 1. During operation, carrier gas 120 flows into precursor vessel 302, and carries precursor 124 and catalyst 202 to reaction chamber 110. Nanowires can be formed directly on or in product vessel(s) 114 (e.g., the product vessel is the support), or on a support in the product vessel(s).

Referring to FIG. 4, reaction apparatus 400 for horizontal fluidized bed C-CVD includes inlet 102, mass flow controller 106, catalyst vessel 404, furnace 108, reaction chamber 110, and exhaust outlet 112. One or more product vessels 114 may be positioned in reaction chamber 110. Carrier gas/precursor source 406 can be coupled to inlet 102. Catalyst vessel 404 includes a catalyst, such as chloroauric acid, in a liquid phase. Other details may be similar to those described with respect to FIG. 1. During operation, carrier gas/precursor source flows into catalyst vessel 404 and carries precursor 124 and catalyst 202 flow over product vessel(s) 114 in reaction chamber 110, forming nanowires 206 in the product vessel(s). Nanowires can be formed directly on or in product vessel(s) 114 (e.g., the product vessel is the support), or on a support in the product vessel(s).

In some cases, catalyst 202, or supported catalyst 116, is placed directly in reaction chamber 110. In an example, reaction chamber 110 is filled or partially filled with supported catalyst 116 (e.g., supported catalyst 116 may be directly in contact with an interior surface of reaction chamber 110, rather than positioned on one or more product vessels).

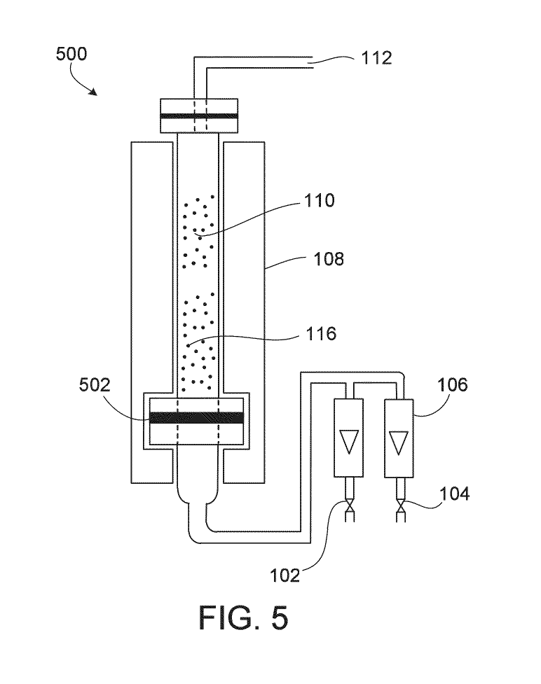

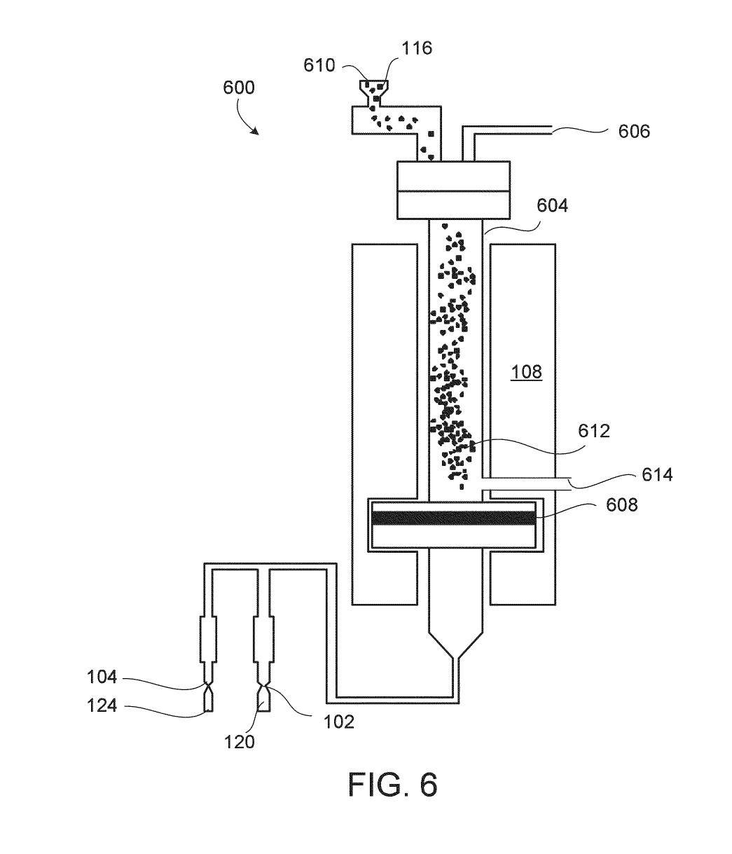

Referring to FIG. 5, reaction apparatus 500 for vertical fluidized bed C-CVD includes inlets 102 and 104, mass flow controllers 106, distributor 502, furnace 108, reaction chamber 110, and exhaust outlet 112. Reaction chamber 110 is filled or partially filled with supported catalyst 116. Other details may be similar to those described with respect to FIG. 1.

The processes described with respect to FIGS. 1, 3, 4, and 5 can be continuous, for example, when a supply of catalyst and precursor are provided to reaction chamber 110 and nanowires 206 are removed from reaction chamber 110 without an interruption in the production process. FIG. 6 depicts reaction apparatus 600 for fluidized bed C-CVD, capable of continuous production of nanowires. Reaction apparatus 600 includes gas inlets 102 and 104, reaction chamber 604, exhaust outlet 606, and distributor 608. Supported catalyst 116 can enter reaction chamber 604 through solid inlet 610. A mixture of carrier gas 120 and precursor 124 can enter reaction chamber 604 through distributor 608, and react under conditions sufficient to grow nanowires on supported catalyst 116. Nanowire-laden support 612 can be removed through solid outlet 614. Thus, a continuous supply of precursor 124 and supported catalyst 116 can be provided to reaction chamber 604, and nanowire-laden support 612 can be continuously removed from the reaction chamber.

### EXAMPLES

### Example 1

A supported catalyst was prepared by disposing gold nanoparticles onto a silica (SiO₂) support. The supported catalyst was prepared by impregnation. First, HAuCl₄, SiO₂ nanoparticles, and deionized water are mixed and heated at 80° C. for 2 hours and stirred at 350 rpm. The resulting mixture is ultracentrifuged at 50,000 rpm for 10 minutes at room temperature, and the product is cleaned with deionized water. The pH of the Au/SiO₂ solution is stabilized with ammonium hydroxide, and the product is cleaned with deionized water via ultracentrifugation. The product is dried overnight at 100° C., and then calcined at 400° C. for four hours.

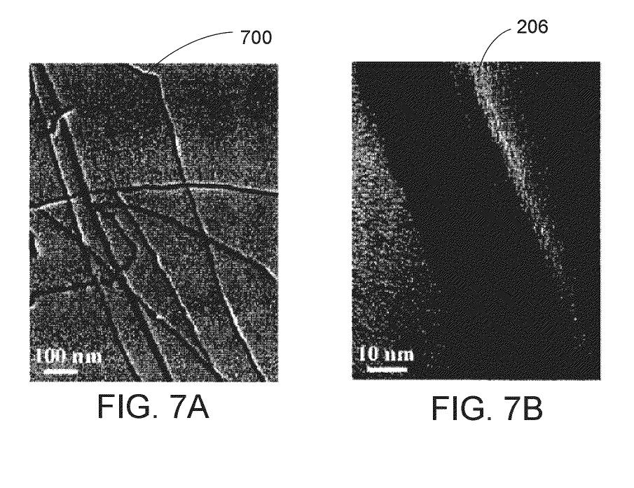

The supported catalyst was loaded on ceramic boats and inserted into a horizontal reaction chamber of a C-CVD fluidized bed reaction apparatus similar to that shown in FIG. 4. The reaction chamber was heated to 500° C., and a mixture of hydrogen and silane was introduced into the reactor, with a volume ratio of silane/hydrogen of 1.5. In about 25 minutes, silicon nanowires were formed in the ceramic boats. FIGS. 7A and 7B show high resolution transmission electron microscope (HR-TEM) images of the resulting silicon nanowires 700 (scale 3 μm and 50 nm, respectively).

### Example 2

Silicon nanowires were synthesized in bulk quantity on millimeter scale Al₂O₃ spheres decorated with gold nanoclusters using horizontal and vertical C-CVD reaction apparatus. By modifying parameters in the synthesis, both single crystalline and core/shell crystalline-amorphous silicon nanowires were obtained with this nanowire-on-sphere method. Distinction in crystallinity of the nanowires was revealed by high resolution transmission electron microscope (HR-TEM) and electron diffraction patterns. The core/shell crystalline-amorphous silicon nanowires were utilized as the active anode material in lithium ion battery half-cells with the traditional slurry method. Galvanostatic measurements demonstrated the maximum power capacity achievable by the electrodes was 3500 mAh/g and capacity sustained at 1100 mAh/g after 60 cycles of charging-discharging.

Al₂O₃ spheres with diameters of ranging from 0.79 to 1.18 mm (available, for example, from Glen Mills Inc.) were used as the supporting substrate for the synthesis. In this study, the silicon nanowires were synthesized in a low-pressure chemical vapor deposition (LPCVD) system as illustrated in FIG. 1. To form catalytic gold nanoclusters for the growth, gold film with a thickness of 2 nm was deposited on the surface of the spheres by e-beam evaporation. Thermal annealing of the spheres covered in gold film was performed at 530° C. under 20 Torr of pressure with constant flow of 100 sccm of H₂ for 30 minutes. At elevated temperature, gold nanoclusters were formed during the annealing process. The Al₂O₃ spheres decorated with gold nanoclusters were loaded on a quartz boat, and the boat was positioned at the center of a horizontally oriented quartz growth chamber inside the furnace.

During the synthesis, the temperature of the growth chamber was raised to 450° C.-530° C., depending on the requirement of crystallography on the resulting nanowires. The pressure in the chamber was held at about 100 Torr while supplying a substantially constant flow of silane (SiH₄, 2% silane in argon) and hydrogen (H₂, ultra high purity hydrogen) at 111 standard cubic centimeters (sccm) and 20 sccm respectively. The gold nanoclusters served as catalytic sites for silicon nucleation during the VLS process of the synthesis. A variation in nanowire diameter is thought to result at least in part from the non-uniform nanocluster diameter of the catalyst.

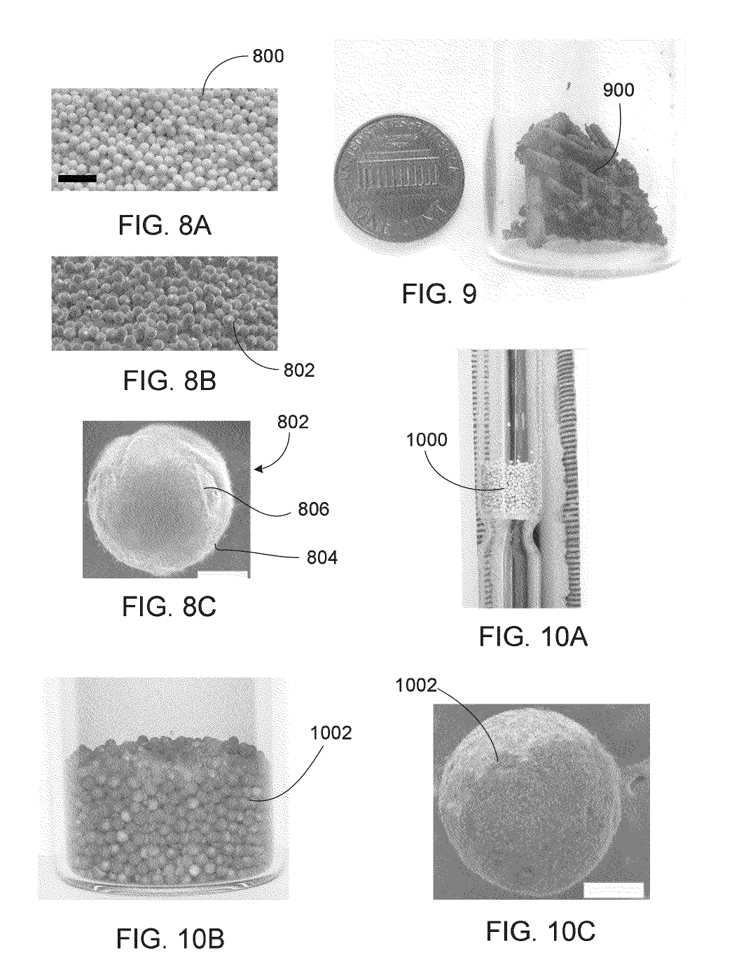

The two photographic images in FIGS. 8A and 8B show the difference in external appearance of supported catalyst 800 (Al₂O₃ spheres, scale bar 4 mm) and nanowire-laden support 802. There is an apparent change in color from white (supported catalyst 800 in FIG. 8A) to brown (nanowire-laden support 802 in FIG. 8B). A SEM image of nanowire-laden support 802 is shown in FIG. 8C (scale bar 300 μm). Support 804 is covered with high density of nanowires 806 grown in various directions. Nanowires 806 were not only grown on Al₂O₃ spheres situated on the surface of the sphere stack, but were also observed on the surface of the spheres buried underneath. Due to the large diameter of the spheres, the precursor (SiH₄) was able to diffuse through the interstices between the spheres situated on the surface, and can reach the buried spheres during the synthesis, facilitating synthesis of silicon nanowires in bulk quantity.

The silicon nanowires can be removed from the surface of the spheres by ultrasonicating the spheres in a solvent or by vibrating the spheres in a solvent. Suitable solvents include, for example, isopropyl alcohol, dimethylformamide, n-butanol, n-propanol, ethanol, and methanol. To extract nanowires from the solution, the solution was dispersed onto a piece of microscope slide, and the solvent was evaporated at an elevated temperature (80° C.), leaving behind a layer of nanowire film. After removing the nanowire film from the microscope slide, the nanowires appeared in “rolls” or “flakes.” FIG. 9 shows a photograph of 80 mg of free-standing silicon nanowire rolls or flakes 900 in a glass vial.

To further increase the yield of the synthesis method, the growth chamber along with the furnace can be oriented in the vertical direction, as depicted in FIG. 5. The aforementioned configuration of the growth chamber allowed a greater quantity of Al₂O₃ spheres to be loaded in the reaction chamber, hence leading to higher yield of the silicon nanowires. Photographic images of the Al₂O₃ spheres before and after synthesis are shown in FIG. 10A (supported catalyst 1000) and FIG. 10B (nanowire-laden support 1002), respectively. FIG. 10C shows an SEM image of an Al₂O₃ sphere with as-grown silicon nanowires (nanowire-laden support 1002, scale bar 400 μm).

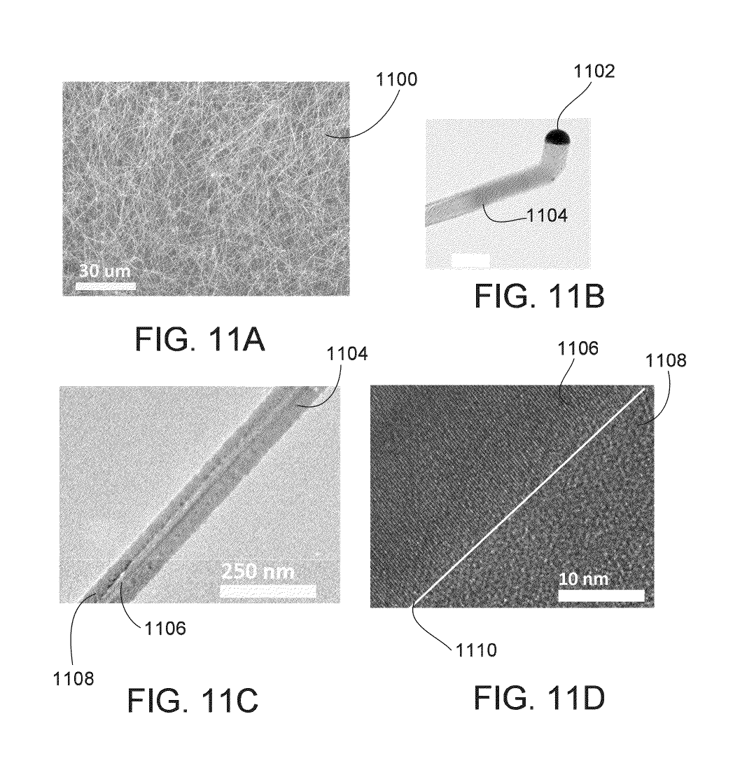

Both single crystalline and c-a core/shell silicon nanowires were synthesized by the nanowire-on-sphere methodology. Having the ability to produce both single crystalline and c-a core/shell silicon nanowires in bulk quantity provides a source for scaling up the aforementioned nanowire related applications. FIG. 11A shows a SEM image of the c-a core/shell silicon nanowires 1100 grown on Al₂O₃ spheres. The nanowires are between 40-100 μm in length, and the density is approximately 6 nanowires per μm². In FIG. 11B, gold particle (catalyst 1102) can be seen on the tip of nanowire 1104, suggesting that the nanowire growth was based on the VLS mechanism. FIG. 11C is a TEM image showing the core/shell morphology of nanowire 1104, with core 1106 and shell 1108. The clear contrast reveals the conspicuous boundary between crystalline core 1106 and amorphous shell 1108.

To illustrate the crystalline-amorphous core/shell structure of the nanowires, a high resolution transmission electron microscopic (HR-TEM) image is presented in FIG. 11D. The periodic planes in crystalline core 1106 gave rise to constructive interference of the deflected electron waves in the TEM and resulted in lattice fringes as shown in the figure. There is a clear boundary 1110 between the fringes resulting from the crystalline lattice of the core and the amorphous shell 1102 of the silicon nanowire in FIG. 11D. The c-a core/shell nanowires can be controllably synthesized by sustaining the temperature of the reaction chamber at 530° C. during the growth.

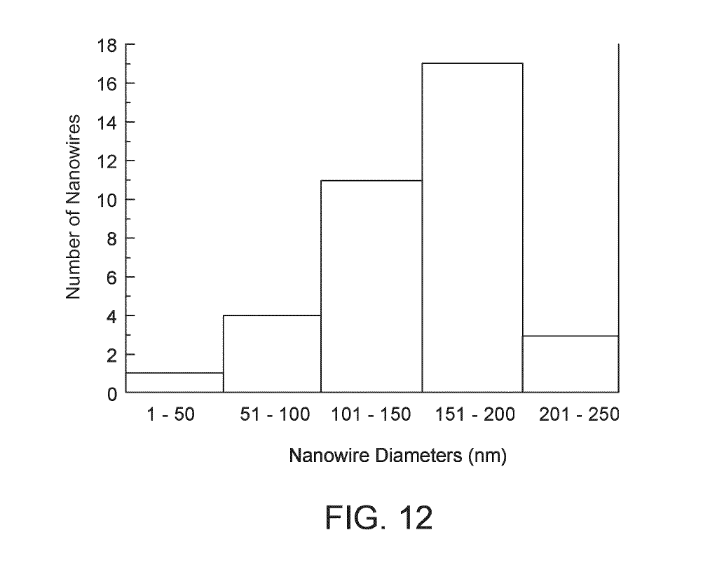

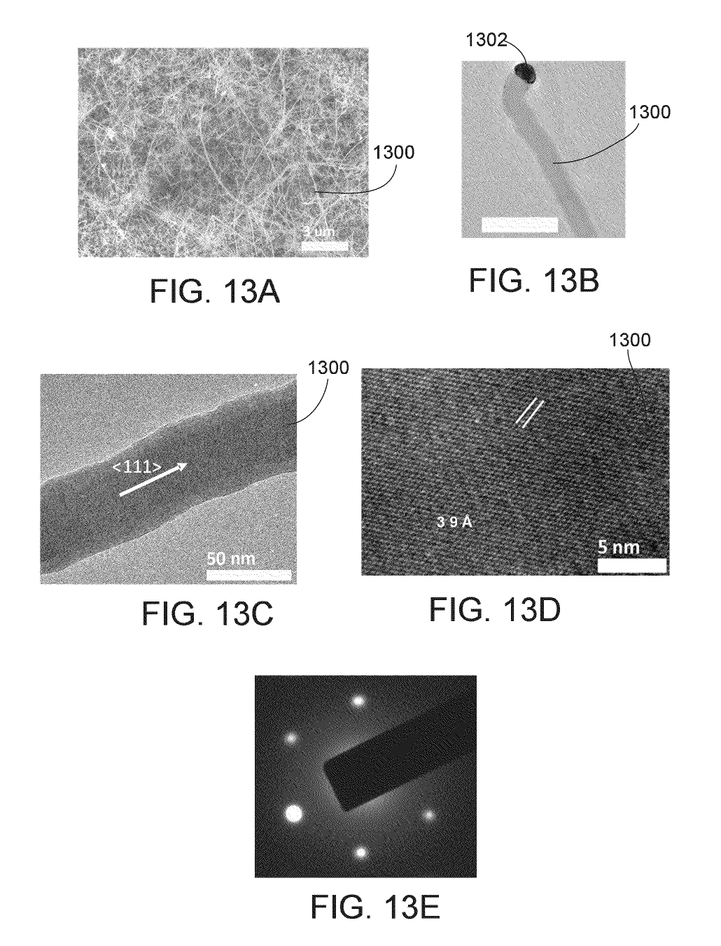

Many of the nanowires synthesized at the aforementioned temperature exhibit diameters ranging between 151 and 200 nm as shown in the distribution in FIG. 12. In some cases, the variation in diameter of the nanowires may be ascribed to the property of lateral diffusion of the gold droplets during the annealing process and during the growth.

Single crystalline silicon nanowires were also synthesized on Al₂O₃ spheres. The process of the synthesis was the same as the procedure described previously, except for the growth temperature, which was controlled at 455° C. to form single crystalline nanowires. The volume of the silicon-gold alloy was controlled by the temperature during the VLS process hence resulting in the difference in diameter of the nanowires.

A FESEM image of the as-grown single crystalline nanowires 1300 is shown in FIG. 13A. The average length of the nanowires is estimated to be 10 μm, which is at least four times shorter than that of the c-a core/shell nanowires. The density of the nanowires is approximately 10 NW/μm². FIG. 13B shows gold tip 1302 formed at one end of silicon nanowire 1300 (scale bar 100 nm). A HR-TEM image of one of the silicon nanowires 1300 is shown in FIG. 13C. The diameter of nanowire 1300 is 48 nm in the image, which is three times narrower than the diameters of the core/shell silicon nanowires. The spacing between contiguous planes in the silicon nanowire was measured to be 3.9 Angstroms based on the lattice fringe seen in FIG. 13D. The plane spacing corresponds to the <111> direction as the preferential growth direction of the nanowire. FIG. 13E is an electron diffraction pattern from the silicon nanowire.

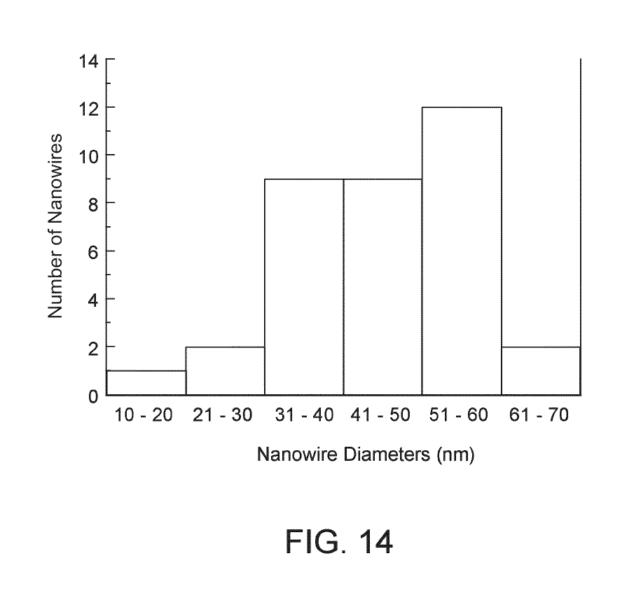

The diameter of the nanowires synthesized by the aforementioned example varies from 10 to 70 nm, having the majority of the diameter of the nanowires lies between 30 to 60 nm as shown in the distribution in FIG. 14. As shown by the results, crystalline silicon nanowires can be synthesized on the Al₂O₃ spheres by varying the growth temperature in the reaction chamber. These crystalline nanowires with shorter diameter can be used for study of their electronic transport properties. The carrier mobility of the silicon nanowires can be improved by incorporating impurity n-type or p-type dopant atoms into the nanowires with this scheme. A gaseous phase dopant, for instance phosphine (PH₃) or diborane (B₂H₆) can be introduced into the reaction chamber during the synthesis.

As mentioned earlier, c-a core/shell silicon nanowires have been demonstrated to be a desirable anode material for lithium-ion batteries. To demonstrate an application of the silicon nanowires obtained methods described herein, electrochemical properties of the c-a core/shell silicon nanowires were studied. The silicon nanowires were utilized as active materials in the electrode of electrochemical cells. The electrodes were made by mixing the silicon nanowires with SUPER P Conductive Carbon Clack (available from TIMCAL Graphite & Carbon), and sodium carboxymethylcellulose (CMC) (MW90 000, Aldrich) in water (10% weight) to form a uniform slurry, and then spread onto a copper foil using a stainless steel blade. The electrode was dried at 50° C. in air overnight and maintained at room temperature in argon for two hours just prior to cell assembly to remove any residual water vapor. The loading density of the silicon nanowires was estimated to be 1 mg/cm². CR2032 coin cells were assembled in an argon-filled glove box using the as-prepared silicon nanowires anodes as working electrodes and lithium metal foil as counter electrodes. The electrolyte was 1M LiClO₄ dissolved in a 1:1 (weight ratio) mixture of ethylene carbonate (EC) and diethyl carbonate (DEC).

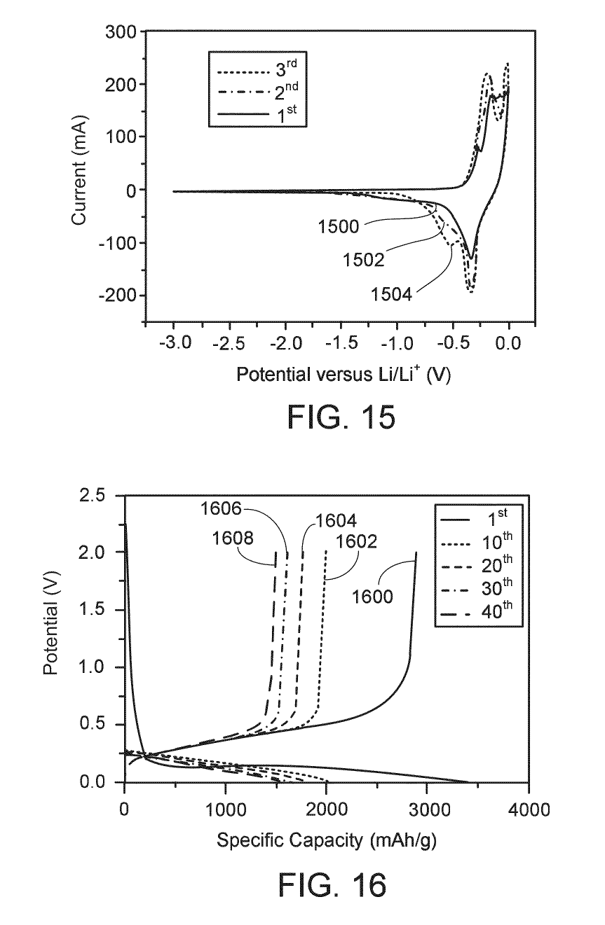

The cyclic voltammetry (CV) profile of the silicon nanowire electrodes was obtained by a potentiostat (Gamry Reference 600 Potentiostat/Galvanostat) using a potential window of 0.01 volt to 3.0 volt for three cycles. The result of the CV measurement is shown in FIG. 15 with a scan rate of 0.05 mV/sec. When the potential was incremented from −3.0V to 0.01V during the first discharging cycle, the silicon nanowires exhibited typical c-a core/shell features. First, there is a peak at around 250 mV due to lithiation of the a-silicon shell. Second, the peak near 130 mV is attributed to the amorphorization of c-silicon during first lithiation process. Furthermore, further discharging results in the formation of a new phase, Li₁₅Si₄, from amorphous lithium-silicon alloy at the peak potential around 55 mV. Upon charging process, the sharp peak at 390 mV indicates a transformation by means of coexistence of two phases of crystalline and amorphous lithium-silicon alloy. After the first cycle of discharge and charge between 3.0-0.01 V (plot 1500), the peak for c-silicon almost disappeared, demonstrating the c-a shell structure turned into amorphous phase. Although there were changes of the structure leading to changes of the peaks, the second and the third cycles (plots 1502 and 1504, respectively) match well, implying that the system reached a steady state.

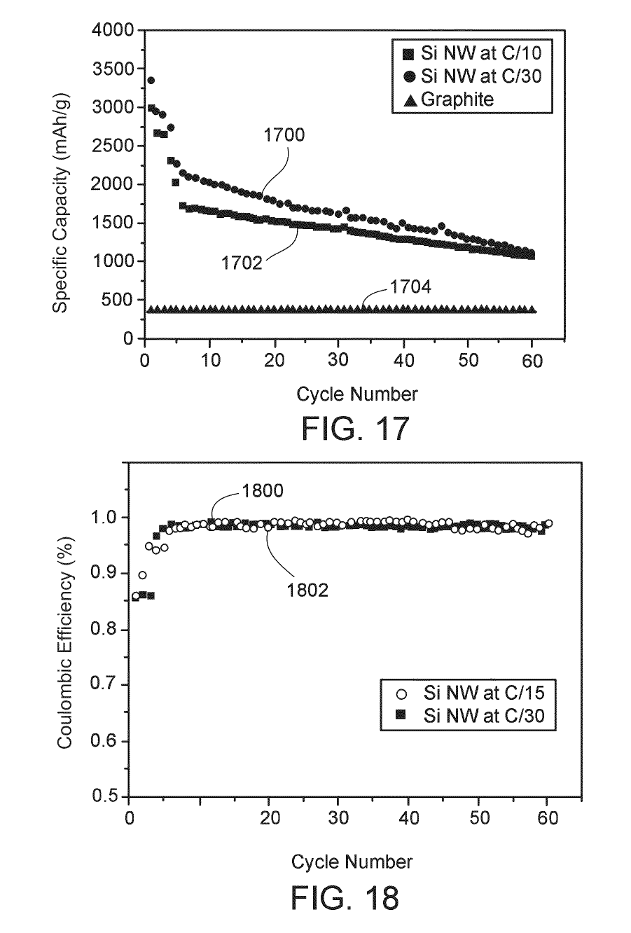

FIGS. 16 and 17 display the galvanostatic (GV) charging/discharging measurements, carried out by a battery testing system (MSTAT Electrochemical Testing System, Arbin Instruments), to determine the specific capacity (Cₛₚ) and the Coulombic efficiency of the devices in a two-electrode configuration. Calculations of different current rates were based on the capacity in the first discharging process. FIG. 16 shows the cycling performance of the silicon nanowire electrodes up to 40 cycles with a current rate C/30. The 1^{st}, 10^{th}, 20^{th}, 30^{th}, and 40^{th} cycles are shown by plots 1600, 1602, 1604, 1606, and 1608, respectively. A slow cycling current reveals electrochemical information with regard to electrode structure. In the initial state, the potential dropped to 200 mV and maintained a prolonged flat plateau at around 100 mV, then gradually decreased to zero. This plateau likely resulted from coexistence of a partially lithiated a-silicon shell accompanied by amorphorization of c-silicon core. The capacity in the first discharging part reaches up to 3500 mAh/g, very close to the theoretical capacity of silicon. With respect to the following cycles, the plateaus were stable at 240 mV, consistent with FIG. 15 that after first cycle, almost all the c-a core/shell structures transformed into amorphous phase. A small plateau is observed at about 50 mV, believed to be associate with the emergence of a new phase, which can also be understood in connection with FIG. 14.

To further investigate the galvanostatic behaviors of the silicon nanowires from bulk synthesis, the electrode was cycled with two different current rates, C/30 and C/10. The relation between discharging specific capacity and cycle number can be seen in FIG. 17. The silicon nanowire electrodes displayed high capacity value at C/30 (plot 1700) and C/10 (plot 1702) in continuous 60 cycles, which is more than two times the common anode material graphite (plot 1704). Performance can be attributed at least in part to the small diameter of nanowires allowing for better accommodation, and one-dimensional electronic pathways benefiting efficient charge transport.

The Coulombic efficiency of these devices is calculated and plotted in FIG. 18, which shows battery performance of the silicon nanowires. At the beginning of several cycles, the efficiencies at two current rates C/15 (plot 1800) and C/30 (plot 1802) improved up to around 90%. During all the following cycles, the values stayed between 98-99%.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

What is claimed is:

1. A method comprising:
contacting a gas-phase precursor comprising a metal or a semiconductor with a catalyst in a reaction chamber comprising a support under conditions suitable for growth of nanowires comprising the metal or the semiconductor on the support to yield a nanowire-laden support in response to interaction between the gas-phase precursor and the catalyst;
removing the nanowire-laden support from the reaction chamber; and
separating the nanowires from the support.

2. The method of claim 1, wherein the gas-phase precursor and the catalyst are contacted in a fluidized bed reactor.

3. The method of claim 1, wherein the precursor comprises silicon, germanium, zinc, indium, tin, or a combination thereof.

4. The method of claim 1, wherein the catalyst is a gas-phase catalyst.

5. The method of claim 1, wherein the catalyst comprises an organometallic compound or a metal.

6. The method of claim 5, wherein the catalyst comprises gold.

7. The method of claim 1, wherein the nanowires are single crystalline nanowires, polycrystalline nanowires, amorphous nanowires, core/shell nanowires, or a combination thereof.

8. The method of claim 7, wherein the nanowires comprise core/shell nanowires comprising a core and a shell, and wherein the core and the shell are independently single crystalline, polycrystalline, or amorphous.

9. The method of claim 1, wherein the catalyst is adhered to the support, and wherein contacting the gas-phase precursor with the catalyst comprises causing the gas-phase precursor to flow over the support.

10. The method of claim 1, wherein the support is a particulate support.

11. The method of claim 10, wherein the support is spherical in shape.

12. The method of claim 10, wherein the support comprises Al₂O₃.

13. The method of claim 1, wherein the support is substantially free of the metal or the semiconductor of the precursor.

14. The method of claim 1, wherein the reaction chamber is configured such that the gas-phase precursor flows upwardly through the reaction chamber from an inlet to an exhaust outlet.

15. The method of claim 1, wherein an interior of the reaction chamber is substantially isolated from an environment surrounding the reaction chamber.

16. The method of claim 1, further comprising providing additional amounts of the gas-phase precursor and the catalyst to the reaction chamber while an interior of the reaction chamber is substantially isolated from an environment surrounding the reaction chamber.

17. The method of claim 1, wherein an interior of the reaction chamber is heated to a temperature between 350° C. and 700° C.

18. Nanowires produced according to the method of claim 1.

19. An anode for a lithium ion half-cell comprising nanowires produced according to the method of claim 1.

20. A battery comprising nanowires produced according to the method of claim 1.
